(19) United States
(12) Patent Application Publication
(10) Pub. No.: US 2025/0192188 A1
(43) Pub. Date: Jun. 12, 2025

(54) SYSTEMS, DEVICES, AND METHODS FOR PROVIDING HEAT TO ELECTROCHEMICAL CELLS AND ELECTROCHEMICAL CELL STACKS

(71) Applicant: 24M Technologies, Inc., Cambridge, MA (US)

(72) Inventors: Chad Alan HARTZOG, Columbus, IN (US); Mark YOUNG, Lapel, IN (US); Kelly B. LEDBETTER, Carmel, IN (US); Junzheng CHEN, Concord, MA (US); Frank Yongzhen FAN, Arlington, MA (US); Xiaoming LIU, Newton, MA (US)

(21) Appl. No.: 19/058,363

(22) Filed: Feb. 20, 2025

Related U.S. Application Data
(63) Continuation of application No. 18/228,922, filed on Aug. 1, 2023.
(60) Provisional application No. 63/394,341, filed on Aug. 2, 2022.

(51) Int. Cl. H01M 4/62; G01R 31/3835; G01R 31/392; H01M 4/06; H01M 10/48; H01M 50/209; H01M 50/251; H01M 50/264; H01M 50/503; H01M 50/51; H01M 50/531; H01M 50/569; H02S 40/36; H02S 40/38

(52) U.S. Cl. CPC H01M 4/626; G01R 31/3835; G01R 31/392; H01M 4/06; H01M 4/625; H01M 10/48; H01M 50/209; H01M 50/251; H01M 50/264; H01M 50/503; H01M 50/51; H01M 50/531; H01M 50/569; H02S 40/36; H02S 40/38; H01M 2220/10

(57) ABSTRACT

The embodiments described herein involve electrochemical cells that have a heating element integrated into the electrochemical cell. In some aspects, an electrochemical cell comprises an anode current collector, an anode material disposed on the anode current collector, a cathode current collector, a cathode material disposed on a first side of the cathode current collector, a separator disposed between the anode material and the cathode material, and a heating element disposed on a second side of the cathode current collector, the second side opposite the first side. The heating element may include an electrically conductive material and a conductive material and disposed in an insulative material.

### CROSS-REFERENCE TO RELATED APPLICATIONS

This application is a continuation of U.S. patent application Ser. No. 18/228,922, entitled “Systems, Devices, and Methods for Providing Heat to Electrochemical Cells and Electrochemical Cell Stacks,” filed Aug. 1, 2023, which claims priority to and the benefit of U.S. Provisional Patent Application No. 63/394,341 entitled, “Electrochemical Cells and Electrochemical Cell Stacks with Series Connections and Methods of Producing, Operating, and Monitoring the Same,” filed Aug. 2, 2022; the disclosure of which is incorporated herein by reference in its entirety.

### TECHNICAL FIELD

Embodiments described herein relate to electrochemical cells and electrochemical cell stacks including a heating element, and methods of operating and monitoring the same.

### BACKGROUND

Lithium-ion cells demonstrate difficulty charging at cold temperatures. In fact, at certain low temperatures charging lithium-ion cells may become unsafe. The temperature at which charging a cell becomes unsafe depends on the chemistry and material design of the cell. When a lithium-ion cell is charged in a cold environment, ions in the electrolyte deposit in metal form onto the surface of the active material due to a reduced capacity of the active material to absorb the ions. Lithium metal is highly reactive and increases the risk of ions depositing on the surface of the active lithium material each time charge current flows through the cell. Over time, the lithium metal can form a dendrite (e.g., a metal pillar) that can grow into and through the separator causing the cell to go into thermal runaway, even if the cell is at a low temperature and low state of charge (SOC). Electrochemical cells have traditionally been heated via water or pads to distribute heat throughout the cell or cell stack. However, this method increases the cost of the system and adds out-of-process steps, thereby increasing assembly complexity. Therefore, alternative solutions for heating electrochemical cells are needed that may enable charging of the cells at cold temperatures.

### SUMMARY

Embodiments described herein relate to electrochemical cells including a heating element, and methods of operating and monitoring the same. In some aspects, an electrochemical cell comprises an anode current collector, an anode material disposed on the anode current collector, a cathode current collector, a cathode material disposed on a first side of the cathode current collector, a separator disposed between the anode material and the cathode material, and a heating element disposed on a second side of the cathode current collector, the second side opposite the first side. In some embodiments, the heating element may include a conductive material. In some embodiments, the heating element may include an electrically conductive material and an insulative material. In some aspects, an electrochemical cell comprises a first current collector, a first electrode material disposed on a first side of the current collector, a second current collector, a second electrode material disposed on the second current collector, a separator disposed between the first electrode material and the second electrode material, an insulating layer disposed on a second side of the first current collector, the second side opposite the first side, and a metallic sheet disposed on the insulating layer and electrically coupled in series with the first current collector, the metallic sheet including grooves for dissipation of heat. In some aspects, an electrochemical cell comprises a first current collector, a first electrode material disposed on a first side of the first current collector, a second current collector, a second electrode material disposed on the second current collector, a separator disposed between the first electrode material and the second electrode material, an insulating layer disposed on a second side of the first current collector, the second side opposite the first side, and a metallic wire disposed inside the insulating layer following a circuitous path, the metallic wire connected in series with the first current collector.

### BRIEF DESCRIPTION OF THE DRAWINGS

FIG. 1 is a block diagram of an electrochemical cell including a heating element, according to an embodiment.

FIG. 2 is a block diagram of a heating element, according to an embodiment.

FIG. 3A is an electrochemical cell including a heating element, according to an embodiment.

FIG. 3B is an exploded view of the electrochemical cell of FIG. 3A.

FIG. 4A is an electrochemical cell including a heating element, according to an embodiment.

FIG. 4B is an exploded view of the electrochemical cell of FIG. 4A.

FIG. 5A is an electrochemical cell including a heating element, according to an embodiment.

FIG. 5B is an exploded view of the electrochemical cell of FIG. 5A.

FIG. 6A is a circuit diagram of an electrochemical cell stack including heating elements.

FIG. 6B is a circuit diagram of an electrochemical cell with a heating element that produces heat when the electrochemical cell is balanced.

FIG. 7 is a schematic flow chart of a method of heating an electrochemical cell, according to an embodiment.

### DETAILED DESCRIPTION

Embodiments described herein relate to methods of producing, operating, and monitoring electrochemical cells and electrochemical cell stacks. In particular, embodiments described herein relate to electrochemical cells including a heating element. Many electrochemical cell systems already require bypass current devices to balance and equalize charge in the system. Traditionally, balancing is conducted using small resistors on a protection circuit board (PCB or PCBA) that is part of a battery management system (BMS), or through various DC-to-DC converters that move energy from cell to cell, cell to module, or cell to secondary energy rail. When electrochemical cells undergo balancing, heat energy is generated as current flows through the cell. The primary issue with current balancing methods is that the heat energy from balancing must be absorbed by the PCBA of the BMS, which creates a need to either (1) add cooling to the BMS or (2) dramatically increase the BMS size. Balancing an electrochemical cell in the PCBA also significantly limits the amount of current that is available to balance the cells, thereby resulting in very small balance currents and limited total cell capacity for each BMS board. In general, any balance current over 100 mA requires special considerations for heat in the BMS board. Therefore, a more efficient mechanism by which heat may be dissipated from the electrochemical cell would improve overall cell performance.

In order to address the challenges noted above, the embodiments described herein involve electrochemical cells that have a heating element integrated into the electrochemical cell. In some embodiments, the heating element may include a thin metallic sheet including a conductive coating and/or an insulative layer disposed on a current collector in the electrochemical cell. In some embodiments, grooves or cut-outs may be etched into the thin metallic sheet such that the thin metallic sheet has a desired impedance. In some embodiments, the heating element may instead include a metallic wire disposed in an insulative layer electrically connected to a current collector in the electrochemical cell, the metallic wire following a circuitous path to achieve a desired impedance. The heating element can be controlled by the existing BMS system so that few additional components are needed at both the cell, module, and pack level, thereby reducing system complexity and limiting extra costs. The heating element may provide heat to the electrochemical cell to enable charging at lower temperatures. The heating element may also provide increased thermal mass for dissipation of heat generated by balancing current, thereby enabling use of higher balancing currents. The embodiments described herein may allow direct heating of the electrochemical cell or electrochemical cell stack, thereby increasing heating efficiency and reducing loss of heat to the surrounding environment.

A control system for bypassing energy (charge, discharge both) around modules, cells, or packs can ensure safe operation, preventing overcharge and allowing for full formation of each cell. A safety system can monitor temperature, current, and/or voltage to prevent cell damage and thermal runaway due to over-temperature, over-charge or over-discharge.

A safety system can also be used to activate the heating element(s) in the event of an internal or external signal. Activation of the heating element(s) may be used to decrease the total energy of the system to a lower state of charge. A lower state of charge may be selected based on many conditions, such as, but not limited to a vehicle crash or an airport transport mode. In the event of a vehicle crash, it would be advantageous to activate the heating element(s) (even though this may increase the temperature of the system) because this allows the battery system to fully discharge (i.e., a reduces the charge of the battery system) to prevent latent battery fires as the vehicle is transported or disposed. For airport transport, it is desirable to reduce the energy of the battery by selection of a mode, such as a physical button, or a selection from a human interface allows the battery to be safely discharged to a lower energy level, reducing the energy content of the battery to a safe level such as <30% SOC. Other target states of charge may be selected based on many factors. The selection of 30% is based on the limitations of air shipment of lithium ion batteries imposed at the time of this application.

Embodiments described herein can include algorithms to detect cell level failure, internal shorts, and other failure modes using sensors. Sensing can be used to sense or determine cell voltage, temperature, current, module level voltage, module level temperature, module level current, pack level voltage, pack level temperature, and/or pack level current. Algorithms can then be used to diagnose the functional status of each cell in the system. In some cases, sensing can be accomplished via a battery management system (BMS), test system sensing, secondary sensing systems, or any combination thereof. Safety systems can include area temperature (hot spot), fire detection, smoke detection, hydrogen detection, carbon monoxide (CO) detection, carbon dioxide (CO₂) detection, volatile organic compound (VOC) detection, and/or other detection methods to ensure the systems are not damaged or to prevent damage to the system, batteries and facilities during formation. Safety systems can include fire suppression systems to prevent facility damage, active venting systems to prevent facility damage and personal injury, and protection systems to provide propagation protection between cells, modules, and/or battery packs under formation.

In some embodiments, an energy storage system can include a grid or renewable connection for metering energy to the formation system and providing energy to account for efficiency losses. In some embodiments, an energy storage system with building controls can monitor power needs throughout the facility and campus to provide demand load, frequency regulation, peak shaving, load leveling, and/or other grid firming operations. In some embodiments, an energy storage system can serve a formation system and/or other secondary renewable uses, such as charging station power for plug-in-hybrid-electric vehicles (PHEV's), electric vehicles (EV's), or any other suitable implementations.

In some embodiments, electrodes described herein can include conventional solid electrodes. In some embodiments, the solid electrodes can include binders. In some embodiments, electrodes described herein can include semi-solid electrodes. Semi-solid electrodes described herein can be made: (i) thicker (e.g., greater than 100 μm-up to 2,000 μm or even greater) due to the reduced tortuosity and higher electronic conductivity of the semi-solid electrode, (ii) with higher loadings of active materials, and (iii) with a simplified manufacturing process utilizing less equipment. These relatively thick semi-solid electrodes decrease the volume, mass and cost contributions of inactive components with respect to active components, thereby enhancing the commercial appeal of batteries made with the semi-solid electrodes. In some embodiments, the semi-solid electrodes described herein are binderless and/or do not use binders that are used in conventional battery manufacturing. Instead, the volume of the electrode normally occupied by binders in conventional electrodes, is now occupied by: 1) electrolyte, which has the effect of decreasing tortuosity and increasing the total salt available for ion diffusion, thereby countering the salt depletion effects typical of thick conventional electrodes when used at high rate, 2) active material, which has the effect of increasing the charge capacity of the battery, or 3) conductive additive, which has the effect of increasing the electronic conductivity of the electrode, thereby countering the high internal impedance of thick conventional electrodes. The reduced tortuosity and a higher electronic conductivity of the semi-solid electrodes described herein, results in superior rate capability and charge capacity of electrochemical cells formed from the semi-solid electrodes. Since the semi-solid electrodes described herein, can be made substantially thicker than conventional electrodes, the ratio of active materials (i.e., the semi-solid cathode and/or anode) to inactive materials (i.e., the current collector and separator) can be much higher in a battery formed from electrochemical cell stacks that include semi-solid electrodes relative to a similar battery formed form electrochemical cell stacks that include conventional electrodes. This substantially increases the overall charge capacity and energy density of a battery that includes the semi-solid electrodes described herein.

In some embodiments, the electrode materials described herein can be a flowable semi-solid or condensed liquid composition. In some embodiments, the electrode materials described herein can be binderless or substantially free of binder. A flowable semi-solid electrode can include a suspension of an electrochemically active material (anodic or cathodic particles or particulates), and optionally an electronically conductive material (e.g., carbon) in a non-aqueous liquid electrolyte. Said another way, the active electrode particles and conductive particles are co-suspended in an electrolyte to produce a semi-solid electrode. Examples of battery architectures utilizing semi-solid suspensions are described in U.S. Patent Publication No. 2022/0238923 (“the '923 publication”), filed Jan. 21, 2022 and titled “Production of Semi-Solid Electrodes Via Addition of Electrolyte to Mixture of Active Material, Conductive Material, and Electrolyte Solvent,” and Provisional Patent Application No. 63/354,056 (“the '056 application”), filed Jun. 21, 2022 and titled “Electrochemical Cells with High-Viscosity Semi-solid Electrodes, and Methods of Making the Same,” the entire disclosures of which are hereby incorporated by reference.

In some embodiments, electrochemical cells described herein can include components that may have multiple layers and/or may be coated with one or more materials. Examples of electrodes with multiple layers and/or compositional gradients can be found in U.S. Patent Publication No. US 2019/0363351, filed May 24, 2019 (the '351 publication), entitled “High Energy-Density Composition Gradient Electrodes and Methods of Making the Same,” the entire disclosure of which is incorporated herein by reference. Examples of electrodes with selectively permeable membranes are described in U.S. Patent Publication No. US 2019/0348705 entitled, “Electrochemical Cells Including Selectively Permeable Membranes, Systems and Methods of Manufacturing the Same,” filed Jan. 8, 2019 (“the '705 publication”), the disclosure of which is incorporated herein by reference in its entirety.

In some embodiments, power management systems described herein can include any of the aspects described in U.S. Pat. No. 10,153,651 (“the '651 patent”), filed Oct. 9, 2015, and titled, “Systems and Methods for Battery Charging,” the disclosure of which is hereby incorporated by reference in its entirety. In some embodiments, battery management systems described herein can include any of the aspects described in U.S. Patent Publication No. 2022/0278427 (“the '427 publication”), filed May 13, 2022, and titled, “Electrochemical Cells Connected in Series in a Single Pouch and Methods of Making the Same,” the disclosure of which is hereby incorporated by reference in its entirety.

As used in this specification, the singular forms “a,” “an,” and “the” include plural referents unless the context clearly dictates otherwise. Thus, for example, the term “a member” is intended to mean a single member or a combination of members, “a material” is intended to mean one or more materials, or a combination thereof.

The term “substantially” when used in connection with “cylindrical,” “linear,” and/or other geometric relationships is intended to convey that the structure so defined is nominally cylindrical, linear or the like. As one example, a portion of a support member that is described as being “substantially linear” is intended to convey that, although linearity of the portion is desirable, some non-linearity can occur in a “substantially linear” portion. Such non-linearity can result from manufacturing tolerances, or other practical considerations (such as, for example, the pressure or force applied to the support member). Thus, a geometric construction modified by the term “substantially” includes such geometric properties within a tolerance of plus or minus 5% of the stated geometric construction. For example, a “substantially linear” portion is a portion that defines an axis or center line that is within plus or minus 5% of being linear.

As used herein, the term “set” and “plurality” can refer to multiple features or a singular feature with multiple parts. For example, when referring to a set of electrodes, the set of electrodes can be considered as one electrode with multiple portions, or the set of electrodes can be considered as multiple, distinct electrodes. Additionally, for example, when referring to a plurality of electrochemical cells, the plurality of electrochemical cells can be considered as multiple, distinct electrochemical cells or as one electrochemical cell with multiple portions. Thus, a set of portions or a plurality of portions may include multiple portions that are either continuous or discontinuous from each other. A plurality of particles or a plurality of materials can also be fabricated from multiple items that are produced separately and are later joined together (e.g., via mixing, an adhesive, or any suitable method).

As used herein, the term “semi-solid” refers to a material that is a mixture of liquid and solid phases, for example, such as a particle suspension, a slurry, a colloidal suspension, an emulsion, a gel, or a micelle.

As used herein, the terms “activated carbon network” and “networked carbon” relate to a general qualitative state of an electrode. For example, an electrode with an activated carbon network (or networked carbon) is such that the carbon particles within the electrode assume an individual particle morphology and arrangement with respect to each other that facilitates electrical contact and electrical conductivity between particles and through the thickness and length of the electrode. Conversely, the terms “unactivated carbon network” and “unnetworked carbon” relate to an electrode wherein the carbon particles either exist as individual particle islands or multi-particle agglomerate islands that may not be sufficiently connected to provide adequate electrical conduction through the electrode.

As used herein, the terms “energy density” and “volumetric energy density” refer to the amount of energy (e.g., MJ) stored in an electrochemical cell per unit volume (e.g., L) of the materials included for the electrochemical cell to operate such as, the electrodes, the separator, the electrolyte, and the current collectors. Specifically, the materials used for packaging the electrochemical cell are excluded from the calculation of volumetric energy density.

As used herein, the terms “high-capacity materials” or “high-capacity anode materials” refer to materials with irreversible capacities greater than 300 mAh/g that can be incorporated into an electrode in order to facilitate uptake of electroactive species. Examples include tin, tin alloy such as Sn—Fe, tin mono oxide, silicon, silicon alloy such as Si—Co, silicon monoxide, aluminum, aluminum alloy, mono oxide metal (CoO, FeO, etc.) or titanium oxide.

As used herein, the term “composite high-capacity electrode layer” refers to an electrode layer with both a high-capacity material and a traditional anode material, e.g., a silicon-graphite layer.

As used herein, the term “solid high-capacity electrode layer” refers to an electrode layer with a single solid phase high-capacity material, e.g., sputtered silicon, tin, tin alloy such as Sn—Fe, tin mono oxide, silicon, silicon alloy such as Si—Co, silicon monoxide, aluminum, aluminum alloy, mono oxide metal (CoO, FeO, etc.) or titanium oxide.

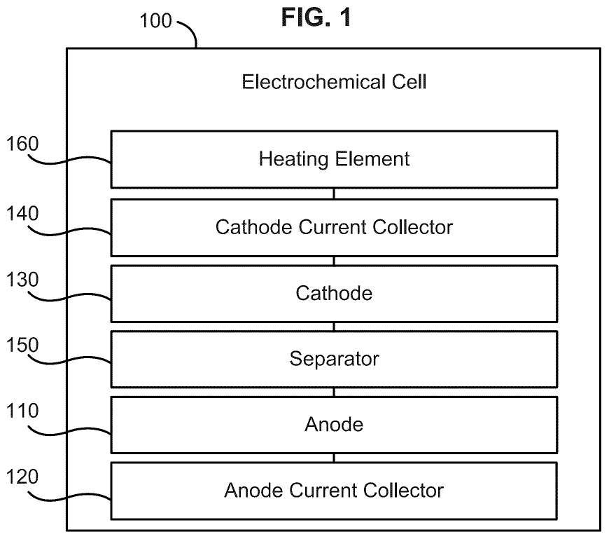

FIG. 1 is a block diagram of an electrochemical cell 100, according to an embodiment. As shown, the electrochemical cell 100 includes an anode material 110 disposed on an anode current collector 120, a cathode material 130 disposed on a first side of a cathode current collector 140, a separator 150 disposed between the anode material 110 and the cathode material 130, and a heating element 160 disposed on a second side of the cathode current collector 140, the second side opposite the first side. In some embodiments, the anode material 110 and/or the cathode material 130 can include a semi-solid electrode material, as described above. In some embodiments, the heating element 160 may be disposed on a first side of the anode current collector 120. The heating element 160 may be electrically connected to the cathode current collector 140 and may generate heat for the electrochemical cell 100 when current is passed through the electrochemical cell 100. Additionally, the heating element 160 may provide increased thermal mass to improve heat dissipation as current is passed through the electrochemical cell 100. As shown, the heating element 160 is electrically connected to the cathode current collector 140 and is immediately adjacent to the cathode current collector 140 in the circuit. In some embodiments, the heating element 160 can be electrically connected to the anode current collector 120 and can be immediately adjacent to the anode current collector 120 in the circuit.

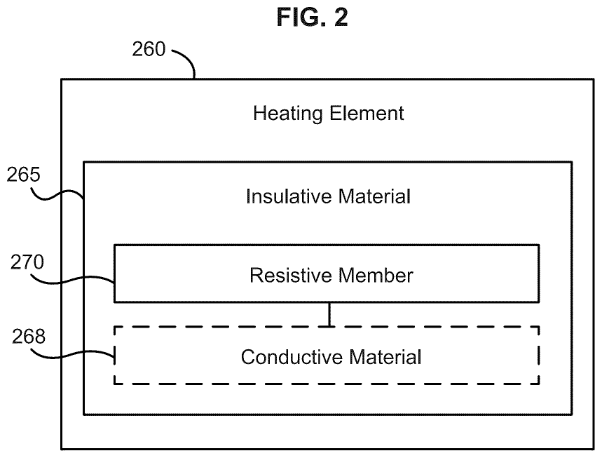

FIG. 2 shows the heating element 260 including a resistive member 270, a conductive material 268, and an insulative material 265. In some embodiments, the resistive member 270 may be formed of an electrically conductive material. The electrically conductive material may include, for example, copper, aluminum, silver, nickel, gold, or any suitable combination thereof. The resistive member 270 can be formed according to any suitable form factor, including but not limited to, a sheet or foil of uniform thickness, a sheet or foil of non-uniform thickness, a non-continuous sheet or foil (e.g., with holes or cut-outs), a wire, and/or combinations thereof. In some embodiments, the resistive member 270 may be coated with a conductive material 268 on at least one of a first side and a second side of the resistive member 270. In some embodiments, the conductive material 268 may be coated on a first side of the insulative material 265. The conductive material 268 may facilitate or enhance heating of the heating element 260 when current is passed through the resistive member 270. The heating element 260 may include an insulative material 265. In some embodiments, the insulative material 265 can include a pouch that surrounds the resistive member 270 or a single layer disposed between a current collector and the resistive member 270. The insulative material 265 may function to isolate the resistive member 270 from the electrical components of the cell (e.g., the terminal, electrode, active material, electrolyte, etc.).

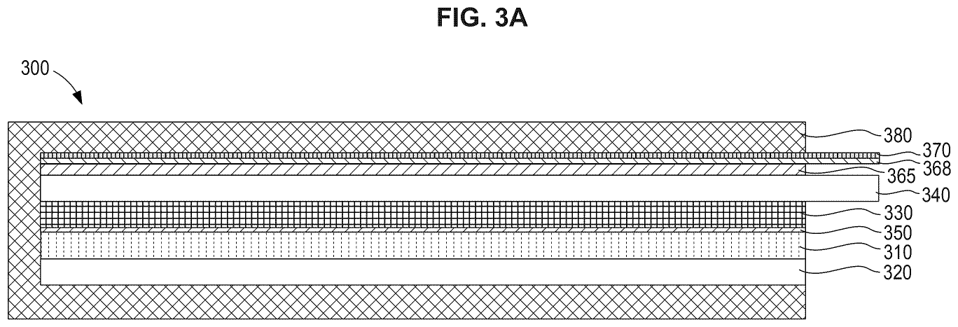

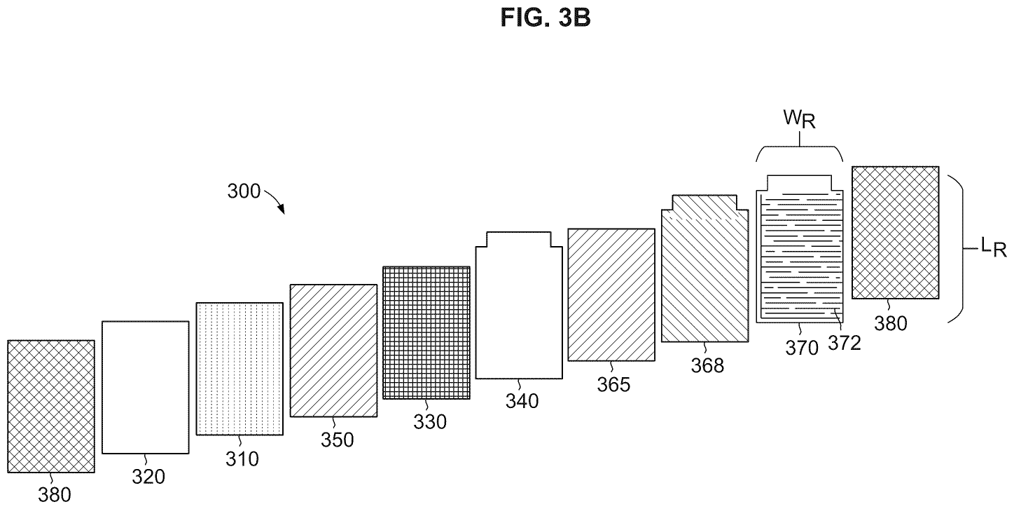

FIGS. 3A-3B are illustrations of an electrochemical cell 300 including a heating element 360, according to an embodiment. FIG. 3A shows a cross-sectional profile view of the electrochemical cell 300. FIG. 3B shows an exploded view of the components of the electrochemical cell 300. As shown in FIG. 3A, the electrochemical cell 300 includes an anode material 310 disposed on an anode current collector 320, a cathode material 330 disposed on a cathode current collector 340, and a separator 350 disposed between the anode material 310 and the cathode material 330. The electrochemical cell 300 further includes a resistive member 370 with a conductive material 368 disposed on a first side of the resistive member 370, an insulative material 365 disposed between the resistive member 370 and the cathode current collector 340, and a pouch material 380 disposed around the electrochemical cell 300. In some embodiments, the anode material 310, the anode current collector 320, the cathode material 330, the cathode current collector 340, and the separator 350 can be the same of substantially similar to the anode material 110, the anode current collector 120, the cathode material 130, the cathode current collector 140, and the separator 150, as described above with reference to FIG. 1. Thus, certain aspects of the anode material 310, the anode current collector 320, the cathode material 330, the cathode current collector 340, and the separator 350 are not described in greater detail herein.

As shown in FIGS. 3A and 3B, the resistive member 370 may be a thin sheet or foil of an electrically conductive material including a surface with grooves or channels 372. The electrically conductive material may include, for example, copper, aluminum, silver, nickel, gold, or any suitable combination thereof. The grooves 372 may be etched (ablated, engraved, carved, cut, melted, stamped, imprinted, debossed, etc.) into the resistive member 370 in a particular pattern to modify the impedance of the resistive member 370, thereby modifying the capacity for heat generation of the resistive member 370 depending on the amount of current passed through the electrochemical cell 300. Accordingly, the grooves 372 are thinned portions of the resistive member 370, as compared to the rest of the resistive member 370 (i.e., the non-grooved portions of the resistive member 370).

The ratio of the thickness of the resistive member 370 in the grooves 372 compared to the thickness of the resistive member 370 in the non-grooved portions may be between about 0.1 and 1. The ratio of thickness between grooved and non-grooved portions can be at least about 0.10, at least about 0.15, at least about 0.20, at least about 0.25, at least about 0.30, at least about 0.35, at least about 0.40, at least about 0.45, at least about 0.50, at least about 0.55, at least about 0.60, at least about 0.65, at least about 0.70, at least about 0.75, at least about 0.80, at least about 0.85, at least about 0.90, at least about 0.95. In some embodiments, the ratio of thickness between grooved and non-grooved portions can be no more than about 1, no more than about 0.95, no more than about 0.90, no more than about 0.85, no more than about 0.80, no more than about 0.75, no more than about 0.70, or no more than about 0.65, no more than about 0.60, no more than about 0.55, no more than about 0.50, no more than about 0.45, no more than about 0.40, no more than about 0.35, no more than about 0.30, no more than about 0.25, no more than about 0.20, no more than about 0.15, no more than about 0.15. Combinations of the above-referenced thickness ratios of the resistive member 370 are also possible (e.g., at least about 0.25 and no more than about 0.95 or at least about 0.50 and no more than about 0.75), inclusive of all values and ranges therebetween.

The resistive member 370 has a length L_{R} and a width W_{R}. In some embodiments, L_{R} can be at least about 1 cm, at least about 2 cm, at least about 3 cm, at least about 4 cm, at least about 5 cm, at least about 6 cm, at least about 7 cm, at least about 8 cm, at least about 9 cm, at least about 10 cm, at least about 20 cm, at least about 30 cm, at least about 40 cm, at least about 50 cm, at least about 60 cm, at least about 70 cm, at least about 80 cm, or at least about 90 cm. In some embodiments, L_{R} can be no more than about 1 m, no more than about 90 cm, no more than about 80 cm, no more than about 70 cm, no more than about 60 cm, no more than about 50 cm, no more than about 40 cm, no more than about 30 cm, no more than about 20 cm, no more than about 10 cm, no more than about 9 cm, no more than about 8 cm, no more than about 7 cm, no more than about 6 cm, no more than about 5 cm, no more than about 4 cm, no more than about 3 cm, or no more than about 2 cm. Combinations of the above-referenced lengths are also possible (e.g., at least about 1 cm and no more than about 1 m or at least about 3 cm and no more than about 10 cm), inclusive of all values and ranges therebetween. In some embodiments, L_{R} can be about 1 cm, about 2 cm, about 3 cm, about 4 cm, about 5 cm, about 6 cm, about 7 cm, about 8 cm, about 9 cm, about 10 cm, about 20 cm, about 30 cm, about 40 cm, about 50 cm, about 60 cm, about 70 cm, about 80 cm, about 90 cm, or about 1 m.

In some embodiments, W_{R} can be at least about 5 mm, at least about 6 mm, at least about 7 mm, at least about 8 mm, at least about 9 mm, at least about 1 cm, at least about 2 cm, at least about 3 cm, at least about 4 cm, at least about 5 cm, at least about 6 cm, at least about 7 cm, at least about 8 cm, at least about 9 cm, at least about 10 cm, at least about 20 cm, at least about 30 cm, or at least about 40 cm. In some embodiments, W_{R} can be no more than about 50 cm, no more than about 40 cm, no more than about 30 cm, no more than about 20 cm, no more than about 10 cm, no more than about 9 cm, no more than about 8 cm, no more than about 7 cm, no more than about 6 cm, no more than about 5 cm, no more than about 4 cm, no more than about 3 cm, no more than about 2 cm, no more than about 1 cm, no more than about 9 mm, no more than about 8 mm, no more than about 7 mm, or no more than about 6 mm. Combinations of the above-referenced widths are also possible (e.g., at least about 5 mm and no more than about 50 cm or at least about 2 cm and no more than about 10 cm), inclusive of all values and ranges therebetween. In some embodiments, W_{R} can be about 5 mm, about 6 mm, about 7 mm, about 8 mm, about 9 mm, about 1 cm, about 2 cm, about 3 cm, about 4 cm, about 5 cm, about 6 cm, about 7 cm, about 8 cm, about 9 cm, about 10 cm, about 20 cm, about 30 cm, about 40 cm, or about 50 cm.

As shown, the grooves 372 extend horizontally along W_{R} with gaps between the grooves 372 both along W_{R} and L_{R} such that current is guided through a particular path on the resistive member 370. The grooves 372 create a tortuosity in the flow path electrons follow through the resistive member 370. Tortuosity is defined as the ratio of the length of the actual flow path (the length of the path current follows through the resistive member 370) to the straight distance between the ends of the flow path (the direct length from a positive terminal of the resistive member 370 to a negative terminal of the resistive member 370). Therefore, by adding more grooves 372, the tortuosity of the resistive member 370 may be increased. The tortuosity ratio may be proportional to the impedance of the resistive member 370, and the impedance of the resistive member 370 may be proportional to the heat generated given a certain amount of current passing through the resistive member 370. A resistive member 370 with more grooves 372 included can generate a larger amount of heat than a resistive member 370 with fewer grooves or no grooves included. Additionally, including the grooves 372 may increase the surface area of the resistive member 370, thereby increasing the ability of the resistive member 370 to dissipate heat. In some embodiments, the resistive member 370 may include more than one thin sheet or foil. In some embodiments, the resistive member 370 may be a continuous thin sheet or foil without grooves or channels 372.

The resistive member 370 can have a tortuosity of at least about 1, at least about 1.5, at least about 2, at least about 2.5, at least about 3, at least about 3.5, at least about 4, at least about 4.5, at least about 5, at least about 5.5, at least about 6, at least about 6.5, at least about 7, at least about 7.5, at least about 8, at least about 8.5, at least about 9, at least about 9.5, at least about 10, at least about 20, at least about 30, at least about 40. In some embodiments, the tortuosity can be no more than about 50, no more than about 40, no more than about 30, no more than about 20, no more than about 10, no more than about 9.5, no more than about 9, no more than about 8.5, no more than about 8, no more than about 7.5, no more than about 7, no more than about 6.5, no more than about 6, no more than about 5.5, no more than about 5, no more than about 4.5, no more than about 4, no more than about 3.5, no more than about 3, no more than about 2.5, no more than about 2, no more than about 1.5. Combinations of the above-referenced widths are also possible (e.g., at least about 5 and no more than about 50 or at least about 2 and no more than about 10), inclusive of all values and ranges therebetween. In some embodiments, the tortuosity can be about 1, about 1.25, about 1.5, about 1.75, about 2, about 2.25, about 2.5, about 2.75, about 3, about 3.25, about 3.5, about 3.75, about 4, about 4.25, about 4.5, about 4.75, about 5, about 5.25, about 5.5, about 5.75, about 6, about 6.25, about 6.5, about 6.75, about 7, about 7.25, about 7.5, about 7.75, about 8, about 8.25, about 8.5, about 8.75, about 9, about 9.25, about 9.5, about 9.75, about 10 cm, about 20 cm, about 30 cm, about 40 cm, or about 50 cm.

In some embodiments, the resistive member 370 can include partially conductive, high resistance materials (e.g., low carbon loaded slurry, alumina, ceramic composites, etc.) such that current flow between the resistive member 370 and the anode current collector 320 and/or the cathode current collector 340 produces the desired heating. In some embodiments, the resistive member 370 can include high conductive, low resistance material (e.g., high carbon loading, metal fill, conductive epoxies, etc.) such that current flow across the surface of the resistive member 370 produces the desired heating.

The resistive member 370 may include a coating of conductive material 368 on at least one of a first side and a second side of the resistive member 370. As shown in FIGS. 3A and 3B, the conductive material 368 is coated onto a first side of the resistive member 370, the first side adjacent to the cathode current collector 340 and the other electroactive components of the electrochemical cell 300. In some embodiments, the conductive material can be coated on a second side of the resistive member 370, the second side opposite the first side (i.e., the second side faces the pouch 380 and the exterior of the electrochemical cell 300). In some embodiments, the conductive material 368 may coat both sides of the resistive member 370. In some embodiments, the conductive material 368 may coat a first side of the insulative material 368. In some embodiments, the conductive material 368 can include a carbon-based material, conductive metal and/or non-metal material, including composites or layered materials. In some embodiments, the conductive material 368 may include, for example, graphite, carbon powder, pyrloytic carbon, carbon black, carbon fibers, carbon microfibers, carbon nanotubes (CNTs), single walled CNTs, multi walled CNTs, fullerene carbons including “bucky balls,” graphene sheets and/or aggregate of graphene sheets, any other conductive material, metal, alloys or combination thereof.

Any suitable method may be used to coat the resistive member 370 with the conductive material 368, including but not limiting to vapor deposition, chemical vapor deposition, physical vapor deposition, atomic layer deposition, metal-organic chemical vapor deposition, nitrogen-plasma assisted deposition, sputter deposition, reactive sputter deposition, electroless deposition, jet deposition, spattering, melt quenching, mechanical milling, spraying, a cold spray process, a plasma deposition process, electrochemical deposition, a sol-gel process, evaporation, or any combination thereof. In some embodiments, the conductive coating 368 can be applied to the resistive member 370 via a liquid coating process, such as applying a liquid slurry or painting, or an extrusion process with or without a hot/cold press process. In some embodiments, the conductive material 368 can be applied to the separator via casting, lamination, calendering, drop coating, pressing, roll pressing, tape casting, or any combination thereof. In some embodiments, the conductive material 368 can be applied via any of the methods described in the '351 publication and/or the '705 publication. The conductive material 368 may facilitate or enhance heating of the heating element 360 when current is passed through the resistive member 370. In some embodiments, the conductive material 368 may be a separate layer from the resistive member 370.

In some embodiments, the conductive material 368 can have a thickness of at least about 100 nm, at least about 200 nm, at least about 300 nm, at least about 400 nm, at least about 500 nm, at least about 600 nm, at least about 700 nm, at least about 800 nm, at least about 900 nm, at least about 1 μm, at least about 2 μm, at least about 3 μm, at least about 4 μm, at least about 5 μm, at least about 6 μm, at least about 7 μm, at least about 8 μm, at least about 9 μm, at least about 10 μm, at least about 11 μm, at least about 12 μm, at least about 13 μm, at least about 14 μm, at least about 15 μm, at least about 16 μm, at least about 17 μm, at least about 18 μm, or at least about 19 μm. In some embodiments, when disposed on the first and/or the second side of the resistive member 370, the conductive material 368 can have a thickness of no more than about 20 μm, no more than about 19 μm, no more than about 18 μm, no more than about 17 μm, no more than about 16 μm, no more than about 15 μm, no more than about 14 μm, no more than about 13 μm, no more than about 12 μm, no more than about 11 μm, no more than about 10 μm, no more than about 9 μm, no more than about 8 μm, no more than about 7 μm, no more than about 6 μm, no more than about 5 μm, no more than about 4 μm, no more than about 3 μm, no more than about 2 μm, no more than about 1 μm, no more than about 900 nm, no more than about 800 nm, no more than about 700 nm, no more than about 600 nm, no more than about 500 nm, no more than about 400 nm, no more than about 300 nm, or no more than about 200 nm. Combinations of the above-referenced thicknesses of the conductive material 368 are also possible (e.g., at least about 100 nm and no more than about 20 μm or at least about 1 μm and no more than about 5 μm), inclusive of all values and ranges therebetween. In some embodiments, when disposed on the first and/or the second side of the resistive member 370, the conductive material 368 can have a thickness of about 100 nm, about 200 nm, about 300 nm, about 400 nm, about 500 nm, about 600 nm, about 700 nm, about 800 nm, about 900 nm, about 1 μm, about 2 μm, about 3 μm, about 4 μm, about 5 μm, about 6 μm, about 7 μm, about 8 μm, about 9 μm, about 10 μm, about 11 μm, about 12 μm, about 13 μm, about 14 μm, about 15 μm, about 16 μm, about 17 μm, about 18 μm, about 19 μm, or about 20 μm.

In some embodiments, the conductive material 368 can have a density of at least about 1.2 g/cm³, at least about 1.3 g/cm³, at least about 1.4 g/cm³, at least about 1.5 g/cm³, at least about 1.6 g/cm³, at least about 1.7 g/cm³, at least about 1.8 g/cm³, or at least about 1.9 g/cm³. In some embodiments, the conductive material 368 can have a density of no more than about 2 g/cm³, no more than about 1.9 g/cm³, no more than about 1.8 g/cm³, no more than about 1.7 g/cm³, no more than about 1.6 g/cm³, no more than about 1.5 g/cm³, no more than about 1.4 g/cm³, or no more than about 1.3 g/cm³. Combinations of the above-referenced densities of the layer of conductive material 368 are also possible (e.g., at least about 1.2 g/cm³ and no more than about 2 g/cm³ or at least about 1.3 g/cm³ and no more than about 2 g/cm³), inclusive of all values and ranges therebetween. In some embodiments, the conductive material 368 can have a density of about 1.2 g/cm³, about 1.3 g/cm³, about 1.4 g/cm³, about 1.5 g/cm³, about 1.6 g/cm³, about 1.7 g/cm³, about 1.8 g/cm³, about 1.9 g/cm³, or about 2 g/cm³.

In some embodiments, the conductive material 368 can include particles with an average particle size (i.e., D50) of at least about 10 nm, at least about 20 nm, at least about 30 nm, at least about 40 nm, at least about 50 nm, at least about 60 nm, at least about 70 nm, at least about 80 nm, at least about 90 nm, at least about 100 nm, at least about 200 nm, at least about 300 nm, at least about 400 nm, at least about 500 nm, at least about 600 nm, at least about 700 nm, at least about 800 nm, at least about 900 nm, at least about 1 μm, at least about 2 μm, at least about 3 μm, at least about 4 μm, at least about 5 μm, at least about 6 μm, at least about 7 μm, at least about 8 μm, at least about 9 μm, at least about 10 μm, at least about 11 μm, at least about 12 μm, at least about 13 μm, at least about 14 μm, at least about 15 μm, at least about 16 μm, at least about 17 μm, at least about 18 μm, or at least about 19 μm. In some embodiments, the conductive material 368 can include particles with an average particle size of no more than about 20 μm, no more than about 19 μm, no more than about 18 μm, no more than about 17 μm, no more than about 16 μm, no more than about 15 μm, no more than about 14 μm, no more than about 13 μm, no more than about 12 μm, no more than about 11 μm, no more than about 10 μm, no more than about 9 μm, no more than about 8 μm, no more than about 7 μm, no more than about 6 μm, no more than about 5 μm, no more than about 4 μm, no more than about 3 μm, no more than about 2 μm, no more than about 1 μm, no more than about 900 nm, no more than about 800 nm, no more than about 700 nm, no more than about 600 nm, no more than about 500 nm, no more than about 400 nm, no more than about 300 nm, no more than about 200 nm, no more than about 100 nm, no more than about 90 nm, no more than about 80 nm, no more than about 70 nm, no more than about 60 nm, no more than about 50 nm, no more than about 40 nm, no more than about 30 nm, or no more than about 20 nm.

Combinations of the above-referenced particle sizes are also possible (e.g., at least about 10 nm and no more than about 20 μm or at least about 1 μm and no more than about 5 μm), inclusive of all values and ranges therebetween. In some embodiments, the conductive material 368 can include particles with an average particle size of about 10 nm, about 20 nm, about 30 nm, about 40 nm, about 50 nm, about 60 nm, about 70 nm, about 80 nm, about 90 nm, about 100 nm, about 200 nm, about 300 nm, about 400 nm, about 500 nm, about 600 nm, about 700 nm, about 800 nm, about 900 nm, about 1 μm, about 2 μm, about 3 μm, about 4 μm, about 5 μm, about 6 μm, about 7 μm, about 8 μm, about 9 μm, about 10 μm, about 11 μm, about 12 μm, about 13 μm, about 14 μm, about 15 μm, about 16 μm, about 17 μm, about 18 μm, or about 19 μm, or about 20 μm.

The heating element may include an insulative material 365. In some embodiments, the conductive material 368 may coat a first side of the insulative material 368, the first side of the insulative material 368 facing towards the resistive member 370. The resistive member 370 may be packaged in an electrically insulating layer or assembly, or co-packaged with the electrochemical cell 300. In some embodiments, the insulative material 365 can be a pouch that surrounds the resistive member 370 and conductive material 368, or a single layer disposed between the resistive member 370 and the other components of the electrochemical cell 300. The insulative material 365 may function to isolate the conductive coating 368 from the electrical components of the electrochemical cell 300 (e.g., the terminal, electrode, active material, electrolyte, etc.) The insulative material 365 may be formed from any suitable material including, for example, polycarbonate, polyethylene, polypropylene, polyimide, mica, polystyrene, glass fibers, FORMEX™, any other suitable insulation material or a combination thereof. In some embodiments, the heating element may include multiple resistive members 360 disposed in the insulative material 365. In some embodiments, the heating element may include about 2 resistive members, 3 resistive members, 4 resistive members, 5 resistive members, 6 resistive members, 7 resistive members, 8 resistive members, 9 resistive members, or 10 resistive members.

In some embodiments, the electrochemical cell 300 may be disposed in an insulative pouch 380. The insulative pouch 380 may have a first film disposed on the heating element 360 and a second film disposed underneath the anode current collector 320, the first film and the second film joined together to form the pouch. In some embodiments, the heating element 360 may instead be disposed on an external surface of the insulative pouch 380. In some embodiments, the heating element 360 including the resistive member 370 and the conductive material 368 may be integrated into the insulative pouch 380. In some embodiments, the conductive material 368 is integrated into or deposited on an inner surface of the insulative pouch 380. In some embodiments, the conductive material 368 is integrated into or deposited on the outer surface of the insulative pouch 380. The insulative pouch 380 may prevent unwanted current from passing between multiple electrochemical cells connected in series during operation of the electrochemical cells. The insulative pouch 380 may be formed from any suitable material including, for example, polycarbonate, polyethylene, polypropylene, polyimide, mica, polystyrene, glass fibers, FORMEX™, any other suitable insulation material or a combination thereof. The electrochemical cell 300 and insulative pouch 380 may be disposed in a structure such as an outer pouch, casing, or housing (not shown). In some embodiments, multiple electrochemical cells can be housed in a stack pouch (not shown). In some embodiments, the stack pouch can include an aluminized pouch. In some embodiments, the heating element 360 may instead be disposed on an external surface of the stack pouch. In some embodiments, the heating element including the resistive member 360 and the conductive material 368 may be integrated into the stack pouch. In some embodiments, the conductive material 368 can be integrated into an inner surface of the stack pouch. In some embodiments, the conductive material 368 can be integrated into an outer surface of the stack pouch.

As shown, the cathode current collector 340, the resistive member 370, and the conductive material 368 may extend away or outward from a first end of the electrochemical cell 300, forming one or more tabs that may be accessible from outside of the outer pouch. In some embodiments, the anode current collector 320 may include a tab extending away or outward from the first end of the electrochemical cell 300. The tabs may function as voltage measurement points for battery monitoring, or as connection points through which the electrochemical cell 300 may be electrically connected in series to other electrochemical cells. The tabs may additionally function as connection points through which the electrochemical cell 300 may be connected to an electronic circuitry such as a battery management system (BMS) (not shown). The BMS may include a circuit board (PCB or PCBA) and may be used, for example, to control current through the cell to monitor the cell, balance the cell, or control heat generated by the cell. In some embodiments, balancing of the electrochemical cell 300 may be conducted at the tabs via the BMS.

Balancing of the electrochemical cell 300 may be beneficial when the electrochemical cell is part of a stack of electrochemical cells. Balancing involves removing electrical charge from or adding electrical charge to the electrochemical cell 300 (e.g., the balance current) to ensure the voltage of any one of the electrochemical cells does not diverge from the pack. Balancing an electrochemical cell may generate heat, which may be absorbed by the PCB of the BMS. The design of electrochemical cell 300 may aid in the distribution of thermal energy. The design may in turn allow for increased current available for balancing. The amount of balance current available can be directly proportional to the cell capacity. With the design of electrochemical cell 300, the balance current can be adjusted to meet the voltage demands of the system and manage the temperature of the system. An increased thermal mass can aid in dissipation of balance current. Thermal mass can be directly proportional to the available balance energy. In some embodiments, an existing cooling system (not shown) can remove heat from the electrochemical cell 300. The incorporation of the heating element 370 can reduce the number of components needed at a module and battery pack level (e.g., thermal pads and/or a water heater can be excluded). The heating element also leads to increased heating efficiency with fewer losses to the ambient environment (i.e., heat goes directly to the electrochemical cell 300).

In some embodiments, the heating element can lead to a marginal increase in system cost (i.e., additional cost for additional electrically conductive material and carbon). However, the manufacturing method can be implemented without new equipment. In some embodiments, the construction of the electrochemical cell 300 can use existing connection methods for cell production, with one additional connection for the heating element 370. In some embodiments, the resistive member 370 may be purchased in existing form from service applications such as food packaging containing aluminum a film layer, or a cell pouch material supplier to further reduce manufacturing complexity and cost.

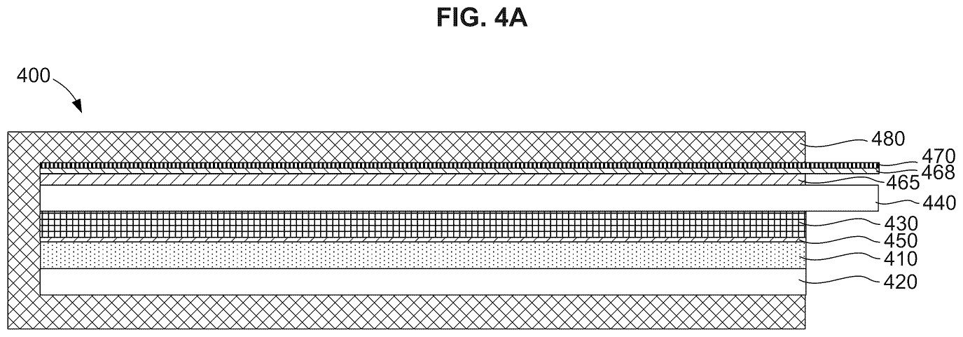

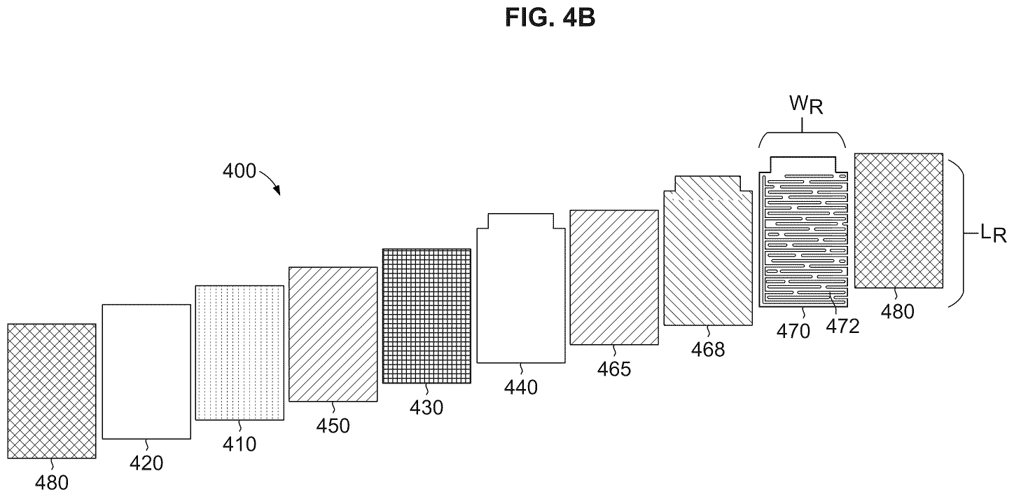

FIGS. 4A-4B are illustrations of an electrochemical cell 400 including a heating element 460, according to an embodiment. FIG. 4A shows a cross-sectional profile view of the elements of the electrochemical cell 400. FIG. 4B shows an exploded view of the electrochemical cell 400. As shown in FIG. 4A, the electrochemical cell 400 includes an anode material 410 disposed on an anode current collector 420, a cathode material 430 disposed on a cathode current collector 440, and a separator 450 disposed between the anode material 410 and the cathode material 430. The electrochemical cell 400 further includes a resistive member 470 with a conductive material 468 disposed on a first side of the resistive member 470, an insulative material 465 disposed between the resistive member 470 and the cathode current collector 440, and a pouch material 480 disposed around the electrochemical cell 400. The electrochemical cell 400 includes a first end and a second end. The cathode current collector 440, the resistive member 470, and/or the conductive material 468 may extend away or outward from the first end of the electrochemical cell 400 to form one or more tabs.

As shown in FIG. 4B, the resistive member 470 may be a thin sheet or foil of electrically conductive material with sections of the thin sheet or foil removed entirely (e.g., cut-outs, holes, gaps) to modify the impedance of the resistive member 470. The resistive member 470 has a length L_{R} and a width W_{R}. Similar to the grooves mentioned above, cut-outs 472 may be removed in a particular pattern to modify the impedance of the resistive member 470, thereby allowing a predetermined amount of heat generation through the resistive member 470 given a certain amount of current passed through the electrochemical cell 400. As shown, sections of the resistive member extending horizontally along W_{R} may be removed such that current is guided through a particular path on the resistive member 470. The cut-outs 472 function similarly to the grooves 372, enabling adjustment of the tortuosity of the electrically conductive material. By adjusting the way in which sections are removed from the resistive member 470, the tortuosity of the resistive member 470 may be increased, thereby increasing the capacity of the resistive member 470 to generate heat. A resistive member 470 with cut-outs 473 can generate a larger amount of heat than a resistive member with less cut-outs or no cut-outs. The resistive member 470 may be purchased in existing form from service applications such as food packaging containing aluminum a film layer, or a cell pouch material supplier to reduce manufacturing complexity and cost. The sections of the resistive member 470 may be removed using standard PCB fabrication methods or with standard flexible circuit technologies.

The resistive member 470 can have a tortuosity of at least about 1, at least about 1.5, at least about 2, at least about 2.5, at least about 3, at least about 3.5, at least about 4, at least about 4.5, at least about 5, at least about 5.5, at least about 6, at least about 6.5, at least about 7, at least about 7.5, at least about 8, at least about 8.5, at least about 9, at least about 9.5, at least about 10, at least about 20, at least about 30, at least about 40, at least about 50. In some embodiments, the tortuosity can be no more than about 50, no more than about 40, no more than about 30, no more than about 20, no more than about 10, no more than about 9, no more than about 8, no more than about 7, no more than about 6, no more than about 5, no more than about 4, no more than about 3, no more than about 2, no more than about 1. Combinations of the above-referenced widths are also possible (e.g., at least about 5 and no more than about 50 or at least about 2 and no more than about 10), inclusive of all values and ranges therebetween. In some embodiments, the tortuosity can be about 1, about 1.25, about 1.5, about 1.75, about 2, about 2.25, about 2.5, about 2.75, about 3, about 3.25, about 3.5, about 3.75, about 4, about 4.25, about 4.5, about 4.75, about 5, about 5.25, about 5.5, about 5.75, about 6, about 6.25, about 6.5, about 6.75, about 7, about 7.25, about 7.5, about 7.75, about 8, about 8.25, about 8.5, about 8.75, about 9, about 9.25, about 9.5, about 9.75, about 10 cm, about 20 cm, about 30 cm, about 40 cm, or about 50 cm.

In some embodiments, the anode 410, the anode current collector 420, the cathode 430, the cathode current collector 440, the separator 450, the resistive member 470, the conductive material 468, and the insulative material 465 can be the same of substantially similar to the anode 310, the anode current collector 320, the cathode 330, the cathode current collector 340, the separator 350, the resistive member 370, the conductive material 368, and the insulative material 365, as described above with reference to FIG. 3. Thus, certain aspects of the anode 410, the anode current collector 420, the cathode 430, the cathode current collector 440, and the separator 450, the resistive member 470, the conductive material 468, and the insulative material 465 are not described in greater detail herein.

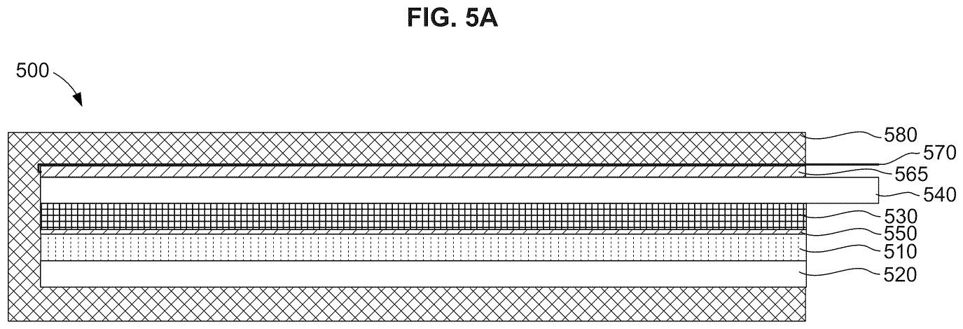

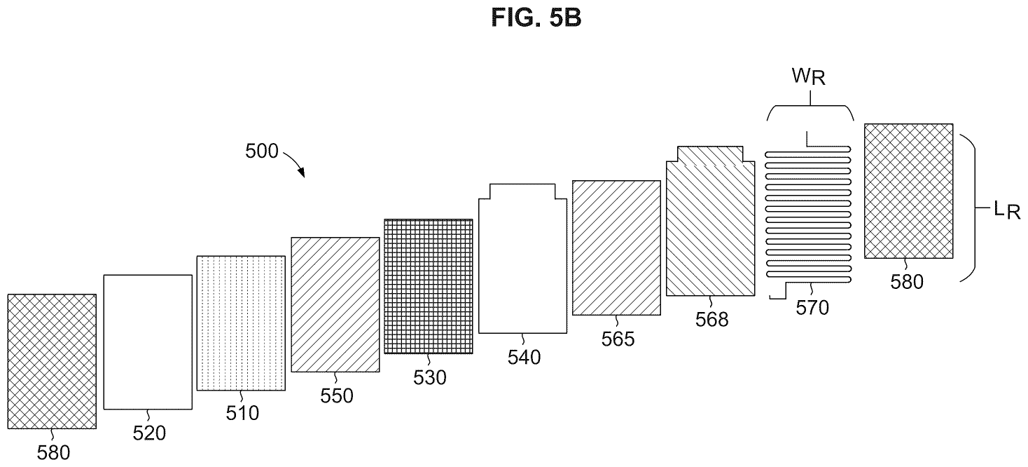

FIGS. 5A-5B are illustrations of an electrochemical cell 500 including a heating element 560, according to an embodiment. FIG. 5A shows a cross-sectional profile view of the elements of the electrochemical cell 500. FIG. 5B shows an exploded view of the electrochemical cell 500. As shown in FIG. 5A, the electrochemical cell 500 includes an anode material 510 disposed on an anode current collector 520, a cathode material 530 disposed on a cathode current collector 540, and a separator 550 disposed between the anode material 510 and the cathode material 430. The electrochemical cell 500 further includes a resistive member 570 with a conductive material 568 coating the resistive member 570, an insulative material 565 disposed between the resistive member 570 and the cathode current collector 540, and a pouch material 580 disposed around the electrochemical cell 500. The electrochemical cell 500 includes a first end and a second end. The cathode current collector 540, the resistive member 570, and/or the conductive material 568 may extend away or outward from the first end of the electrochemical cell 500 to form one or more tabs.

In some embodiments, the resistive member 570 may be a wire with a first terminal end connected in series with a current collector and a second terminal end extending away or outward from the first end of the electrochemical cell 500, the wire following a circuitous (tortuous, twisting) path. The properties of the wire such as the cross-sectional area, length, and path can be adjusted to modify the impedance of the resistive member 570. The wire may be coated with the conductive material 568. By adjusting the path of the wire, the tortuosity of the resistive member 570 may be increased, thereby increasing the capacity of the resistive member 570 to generate heat. Additionally, adjusting the cross-sectional area of the wire may also be used to adjust the impedance of the resistive member 570. A resistive member 570 with more turns over a shorter length L_{R} and/or smaller cross-sectional area can generate a larger amount of heat than a resistive member with less turns and/or larger cross-sectional area.

In some embodiments, the anode 510, the anode current collector 520, the cathode 530, the cathode current collector 540, the separator 550, the resistive member 570, the conductive material 568, and the insulative material 565 can be the same of substantially similar to the anode 310, the anode current collector 320, the cathode 330, the cathode current collector 340, the separator 350, the resistive member 370, the conductive material 368, and the insulative material 365, as described above with reference to FIG. 3. Thus, certain aspects of the anode 510, the anode current collector 520, the cathode 530, the cathode current collector 540, and the separator 550, the resistive member 570, the conductive material 568, and the insulative material 565 are not described in greater detail herein.

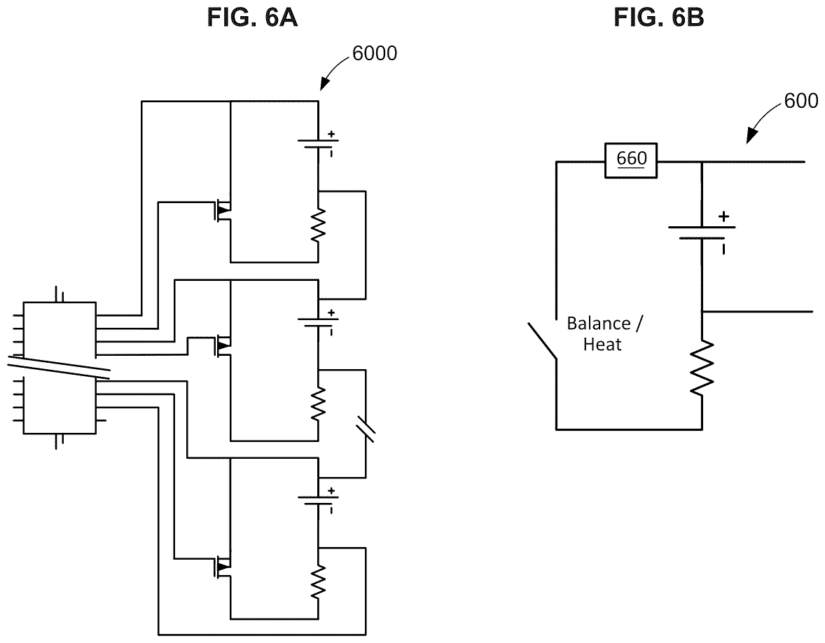

FIG. 6A shows a circuit diagram of an electrochemical cell stack 6000 including heating elements, wherein the electrochemical cells are connected in parallel. As shown, the heating elements may provide an electrical connection between the negative terminal of the electrochemical cell and the BMS to reduce connection points. In some embodiments, a first terminal end of the heating element may electrically connect to the electrochemical cell, and a second terminal end of the heating element may electrically connect to the BMS. FIG. 6B is a circuit diagram of an electrochemical cell 600 with a heating element 660 that produces heat when the electrochemical cell 600 is balanced. As shown, the electrochemical cell 600 has a diversion of current due to the implementation of the heating element 660.

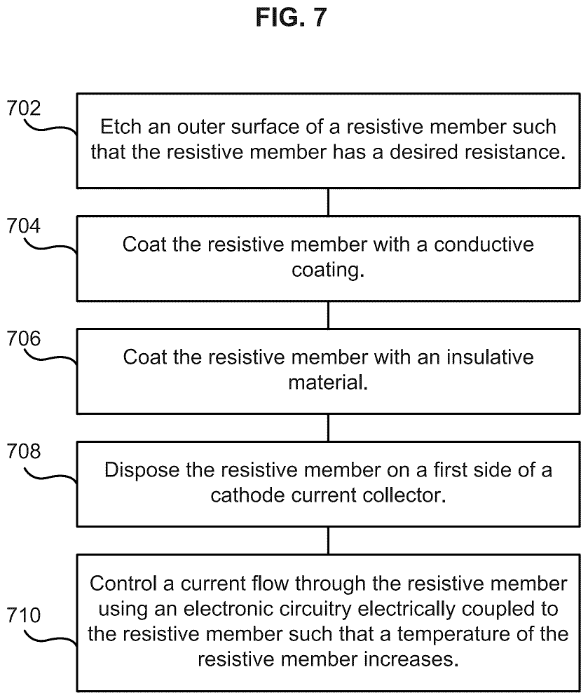

FIG. 7 is a schematic flow chart of a method for heating an electrochemical cell with a heating element, according to an embodiment. While described with respect to the electrochemical cell 300 including the resistive member 370, conductive material 368, and insulative material 365, the method 700 is equally applicable to any electrochemical cell including any heating element described herein. All such variants should be considered to be within the scope of this disclosure.

The method 700 includes etching an outer surface of a resistive member 370 such that the resistive member 370 has a desired impedance, at 702. In some embodiments, sections of the resistive member 370 may be removed entirely to modify the impedance of the resistive member 370. In some embodiments, the resistive member 370 may instead include a wire including a first terminal end that is connected in series with a current collector 340 of the electrochemical cell 300 and that forms a circuitous path with a second terminal end extending outward horizontally from the electrochemical cell 300. At 704, the method includes coating the resistive member 370 with a conductive coating 368. At 706, the resistive member 370 may be disposed in an insulative material 365 to isolate the conductive material 368 from the electrical components of the cell. In some embodiments, the insulative material 365 may be a single layer disposed between the resistive member 370 and a current collector 340 of the electrochemical cell 300. In some embodiments, the insulative material 365 may be a pouch disposed around the resistive member 370. At 708, the method includes disposing the resistive member 370 on a first side of the cathode current collector 340. In some embodiments, the heating element is electrically connected to the cathode current collector 340 and is immediately adjacent to the cathode current collector 340 in the circuit. In some embodiments, the heating element can be electrically connected to the anode current collector 320 and can be immediately adjacent to the anode current collector 320 in the circuit. At 710, current flow through the resistive member 370 is controlled using an electronic circuitry electrically coupled to the resistive member 370 such that a temperature of the resistive member 370 increases. In some embodiments, the electronic circuitry may be an already existing BMS that includes a PCB. In some embodiments, the BMS can be used to monitor the electrochemical cell 300, balance the electrochemical cell 300, and send current through the electrochemical cell 300 to generate heat. In some embodiments, the BMS may include an existing cooling system that may be used to cool the electrochemical cell 300 when heat is generated during balancing of the electrochemical cell 300.

Various concepts may be embodied as one or more methods, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments. Put differently, it is to be understood that such features may not necessarily be limited to a particular order of execution, but rather, any number of threads, processes, services, servers, and/or the like that may execute serially, asynchronously, concurrently, in parallel, simultaneously, synchronously, and/or the like in a manner consistent with the disclosure. As such, some of these features may be mutually contradictory, in that they cannot be simultaneously present in a single embodiment. Similarly, some features are applicable to one aspect of the innovations, and inapplicable to others.

In addition, the disclosure may include other innovations not presently described. Applicant reserves all rights in such innovations, including the right to embodiment such innovations, file additional applications, continuations, continuations-in-part, divisionals, and/or the like thereof. As such, it should be understood that advantages, embodiments, examples, functional, features, logical, operational, organizational, structural, topological, and/or other aspects of the disclosure are not to be considered limitations on the disclosure as defined by the embodiments or limitations on equivalents to the embodiments. Depending on the particular desires and/or characteristics of an individual and/or enterprise user, database configuration and/or relational model, data type, data transmission and/or network framework, syntax structure, and/or the like, various embodiments of the technology disclosed herein may be implemented in a manner that enables a great deal of flexibility and customization as described herein.

All definitions, as defined and used herein, should be understood to control over dictionary definitions, definitions in documents incorporated by reference, and/or ordinary meanings of the defined terms.

As used herein, in particular embodiments, the terms “about” or “approximately” when preceding a numerical value indicates the value plus or minus a range of 10%. Where a range of values is provided, it is understood that each intervening value, to the tenth of the unit of the lower limit unless the context clearly dictates otherwise, between the upper and lower limit of that range and any other stated or intervening value in that stated range is encompassed within the disclosure. That the upper and lower limits of these smaller ranges can independently be included in the smaller ranges is also encompassed within the disclosure, subject to any specifically excluded limit in the stated range. Where the stated range includes one or both of the limits, ranges excluding either or both of those included limits are also included in the disclosure.

The phrase “and/or,” as used herein in the specification and in the embodiments, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the embodiments, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the embodiments, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the embodiments, shall have its ordinary meaning as used in the field of patent law.

As used herein in the specification and in the embodiments, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the embodiments, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

While specific embodiments of the present disclosure have been outlined above, many alternatives, modifications, and variations will be apparent to those skilled in the art. Accordingly, the embodiments set forth herein are intended to be illustrative, not limiting. Various changes may be made without departing from the spirit and scope of the disclosure. Where methods and steps described above indicate certain events occurring in a certain order, those of ordinary skill in the art having the benefit of this disclosure would recognize that the ordering of certain steps may be modified and such modification are in accordance with the variations of the invention. Additionally, certain of the steps may be performed concurrently in a parallel process when possible, as well as performed sequentially as described above. The embodiments have been particularly shown and described, but it will be understood that various changes in form and details may be made.

1. An electrochemical cell assembly, comprising:
an electrochemical cell;
a heating element in thermal communication with at least a portion of the electrochemical cell; and
a controller operatively coupled to the electrochemical cell and the heating element, the controller configured to:
monitor an operating parameter of the electrochemical cell assembly or an event associated with the electrochemical cell assembly, and
based on the operating parameter or the event, cause activation of the heating element to facilitate discharge of the electrochemical cell below a threshold value.

2. The electrochemical cell assembly of claim 1, wherein the operating parameter includes at least one of a temperature, a current, or a voltage of at least a portion of the electrochemical cell assembly.

3. The electrochemical cell assembly of claim 1, wherein the threshold value includes a state of charge of the electrochemical cell of less than about 30%.

4. The electrochemical cell assembly of claim 1, wherein the event includes at least one of an impact event or the electrochemical cell assembly being at a predetermined location.

5. The electrochemical cell assembly of claim 1, wherein the controller is further configured to cause suspension of operation of the heating element based on the operating parameter or the event.

6. The electrochemical cell assembly of claim 1, wherein the activation of the heating element is configured to reduce a state of charge of the electrochemical cell.

7. The electrochemical cell assembly of claim 1, wherein the controller is further configured to:
receive an external signal; and
cause activation of the heating element in response to the external signal.

8. The electrochemical cell assembly of claim 7, wherein the external signal includes a manual setting input by a user.

9. The electrochemical cell assembly of claim 8, wherein the manual setting input includes the electrochemical cell assembly being transported through an airport.

10. The electrochemical cell assembly of claim 1, wherein the event includes at least one of a cell level failure or an internal short circuit.

11. An electrochemical cell assembly, comprising:
an anode material disposed on an anode current collector;
a cathode material disposed on a cathode current collector;
a separator disposed between the anode material and the cathode material;
a heating element in contact with at least one of the anode material, the anode current collector, the cathode material, or the cathode current collector; and
a safety system operatively coupled to the heating element, the safety system configured to activate the heating element in response to at least one of an internal signal or an external signal.

12. The electrochemical cell assembly of claim 11, wherein the internal signal includes a measurement of at least one of a temperature, a voltage, or a current associated with the electrochemical cell assembly.

13. The electrochemical cell assembly of claim 11, wherein the external signal is indicative of an impact event.

14. The electrochemical cell assembly of claim 11, wherein the external signal includes an input by a user.

15. The electrochemical cell assembly of claim 11, wherein:
the anode material, the anode current collector, the cathode material, the cathode current collector, and the separator collectively form an electrochemical cell; and
activating the heating element reduces a state of charge of the electrochemical cell to less than 30%.

16. The electrochemical cell assembly of claim 11, further comprising:
an insulating layer disposed on at least one of the anode current collector or the cathode current collector, the heating element disposed on the insulating layer.

17. The electrochemical cell assembly of claim 11, wherein the heating element includes a planar metallic sheet disposed on a side of the cathode current collector, the planar metallic sheet having sections removed to create a flow path for flow of current.

18. An electrochemical cell system, comprising:
an electrochemical cell;
a heating element disposed proximate to the electrochemical cell; and
a battery management system configured to activate the heating element in response to a triggering condition being met.

19. The electrochemical cell system of claim 18, wherein the heating element contacts at least a portion of the electrochemical cell.

20. The electrochemical cell system of claim 18, wherein the battery management system is configured to determine a functional status of the electrochemical cell.

21. The electrochemical cell system of claim 18, wherein the triggering condition includes an outside stimulus.

22. The electrochemical cell system of claim 21, wherein the outside stimulus includes an impact event.

23. The electrochemical cell system of claim 18, wherein:
the battery management system is further configured to cause discharging of the electrochemical cell in response to the triggering condition being met, and
a heat generated by the heating element is configured to facilitate the discharging.

24. The electrochemical cell system of claim 23, wherein the discharging is to a state of charge of the electrochemical cell to less than 30%.

25. A method of operating an electrochemical cell system, the electrochemical cell system including an electrochemical cell and a heating element, the method comprising:
operating the electrochemical cell;
detecting, via a sensor, a triggering condition in the electrochemical cell; and
in response to detecting the triggering condition, activating, by a controller, a heating element that is in thermal communication with the electrochemical cell.

26. The method of claim 25, wherein the triggering condition includes an external stimulus.

27. The method of claim 26, wherein the external stimulus includes an impact event.

28. The method of claim 26, wherein the external stimulus includes a manual setting input from a user.

29. The method of claim 25, further including:
at least partially discharging the electrochemical cell, a heat generated by the heating element facilitating at least partial discharging of the electrochemical cell.

30. The method of claim 25, wherein the triggering condition includes the electrochemical cell being in an airport transport mode.
